(19) United States
(12) Patent Application Publication
(10) Pub. No.: US 2020/0153272 A1
(43) Pub. Date: May 14, 2020

(54) SMART SOCKET AND MONITORING AND CONTROL SYSTEM USING SAID SOCKET

(71) Applicant: UNIVERSITA' DEGLI STUDI DI FIRENZE, Florence (IT)

(72) Inventors: Marco SOMMA, Florence (IT); Francesco GRASSO, Florence (IT)

(21) Appl. No.: 16/466,498

(22) PCT Filed: Dec. 5, 2017
(86) PCT No.: PCT/IB2017/057634

§ 371 Date: Jun. 4, 2019

(30) Foreign Application Priority Data
Dec. 5, 2016 (IT) 102016000123334

(51) Int. Cl. H02J 13/00; H02J 3/18; G01R 21/06

(52) U.S. Cl. CPC H02J 13/00002; G01R 21/06; H02J 13/00006; H02J 3/18

(57) ABSTRACT

A smart socket for monitoring electric operating parameters of a load in an electric power network. The socket comprises at least one voltage sensor and one current sensor interfaced with a control unit configured to read the electric mains voltage and drawn current values when the socket is inserted between the load and the electric power network, a communication module interfaced with the control unit to send data and receive controls from a remote supervision unit. The socket also comprises load operation control devices, which operate according to the commands received from the communication module and/or the controls preset in the control unit.

### FIELD OF THE INVENTION

The invention relates to the sector of Smart Grids and Smart Metering within the scope of power grids.

### STATE-OF-THE-ART

The term “Smart Grid” is understood to mean an infrastructure/network controlled smartly, so as to be able to manage the various power flows consciously and provide end users with competitive prices.

Specifically, the ERGEG (Association of 27 European regulators) has formulated the following definition of “Smart Grid”: “The Smart Grid is a power supply, which efficiently integrates and manages the conduct and action of all users connected to the power supply (generators, sampling points, and generation and sampling points) with the aim of guaranteeing a financially efficient operation of the electrical system, with low losses, an elevated level of safety and continuity and quality of the supply”.

A fundamental part of Smart Grids is Smart Metering, the object of which is to know consumption profiles in real time, thus giving power supply operators the right to create mechanisms provided with greater flexibility, dynamicity, offering customers, the energy consumers, a greater understanding and awareness of their consumptions. A fundamental requisite of Smart Meter is the possibility to record various users' consumption in real-time and send the remotely acquired data.

Several devices are currently known, called smart sockets in jargon, which can measure electrical magnitudes, in particular grid voltage and current absorbed by the load. Although they carry out their role perfectly, they are nonetheless very specific devices able to process the values measured locally and provide broad indications regarding various electrical parameters, such as the power absorbed by the load, which can be used by the power supply operators to offer customers differentiated contracts based on the specific consumption characteristics. Furthermore, the Smart Grid requires sampling capacities and data processing, which go way beyond simple signal samplings and the relative processing.

It is an object of the present invention to produce an improved smart socket and relative monitoring and control system, which can be used within the scope of Smart Grids for actively managing power supply consumptions.

The invention achieves the object with a smart socket comprising at least one voltage sensor and a current sensor interfaced with a control unit configured to read the electric mains voltage and drawn current values when the socket is inserted between the load and the electric power network, a communication module interfaced with the control unit for sending data and receiving commands from a remote supervision unit. The socket also comprises load operation control devices, which operate according to commands received from the communication module and/or controls preset in the control unit.

The socket is not limited to reading voltage and current data, but interacts strongly with the load thanks to the dialogue with one or more remote supervision units, which can read and process such data and send commands to control and optimize the working of the mains.

In fact, the load control devices can comprise simple modules, which act on the load supply circuit, for example, using a break device for the current circulation on the load, such as a relay, an electronic switch or the like, or, combined, either a power factor correction circuit, which reduces the reactive power on the load, or combined, elements, which allow the control unit to interface with the load, so as to allow the control unit to set at least part of the relative operating parameters directly on the load.

To this end, the control unit is advantageously configured to receive control signals from the supervision unit for remotely controlling the turning on/off and, more generally, the working of the load, optimizing consumption or other performance indexes according to the operating parameters monitored.

According to another aspect, the invention relates to a system for monitoring operating parameters of one or more loads in a power supply, which system comprises a supervision unit interfaced with one or more smart sockets described above for reading data related to the electric mains voltage and current drawn by the load (s), when such smart socket (s) are inserted, in series, between the mains and load. Advantageously, the supervision unit can be configured to process parameters from the smart socket(s) to provide an output Power Quality analysis of the mains.

Further objects, characteristics and advantages of the present invention will become clearer from the following detailed description, given by way of example, which is not limiting, illustrated in the appended figures, wherein:

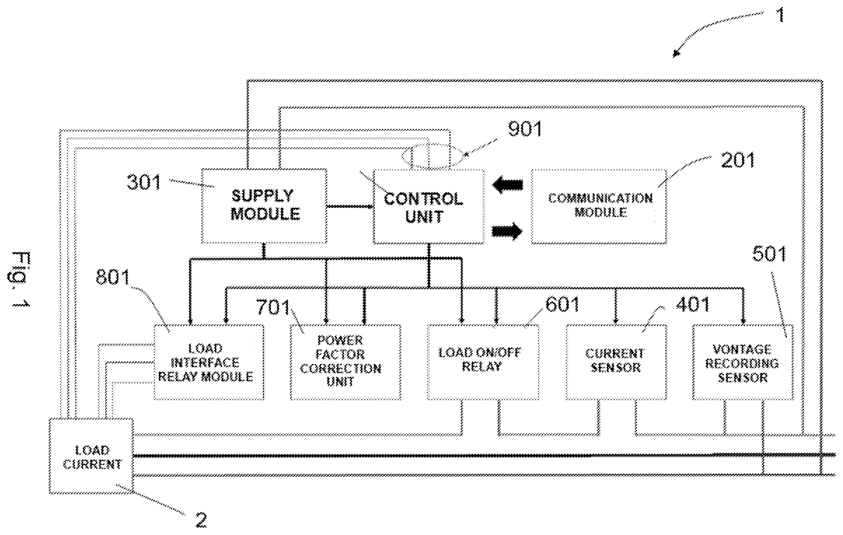

FIG. 1 shows a smart socket according to one embodiment of the invention.

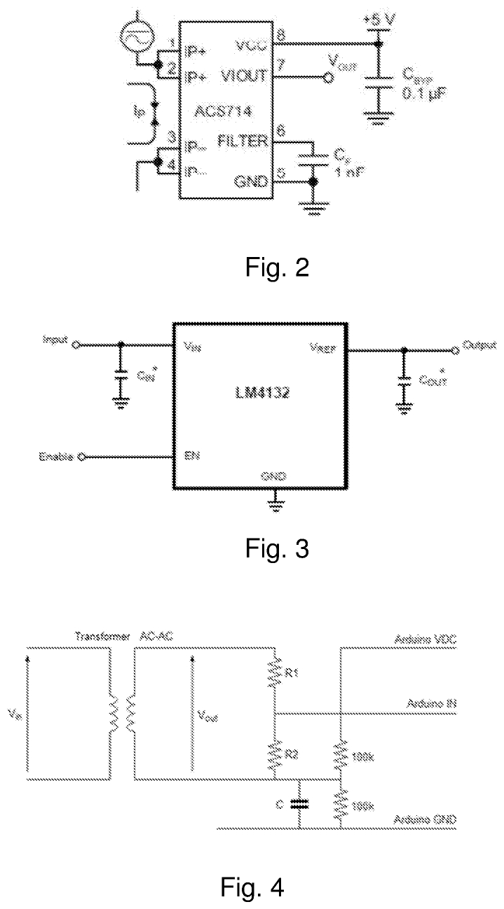

FIG. 2 shows an example of a current sensor usable in the socket according to the invention.

FIG. 3 shows an example of a voltage generator of reference used in combination with the current sensor in the previous figure in an improvement of the invention.

FIG. 4 shows the block diagram of a voltage recording module;

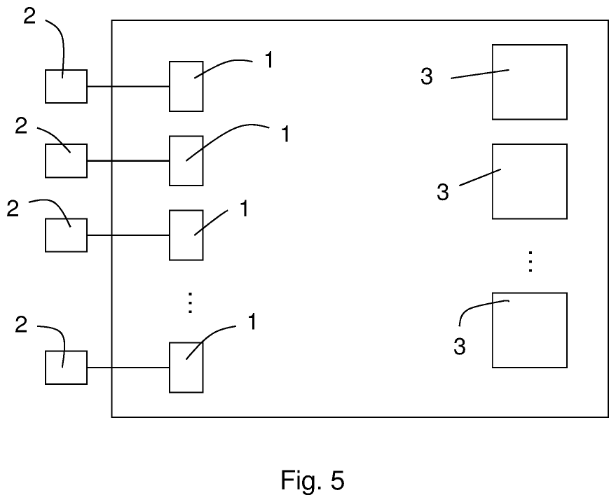

FIG. 5 shows the block diagram of a monitoring and control system according to one embodiment of the invention.

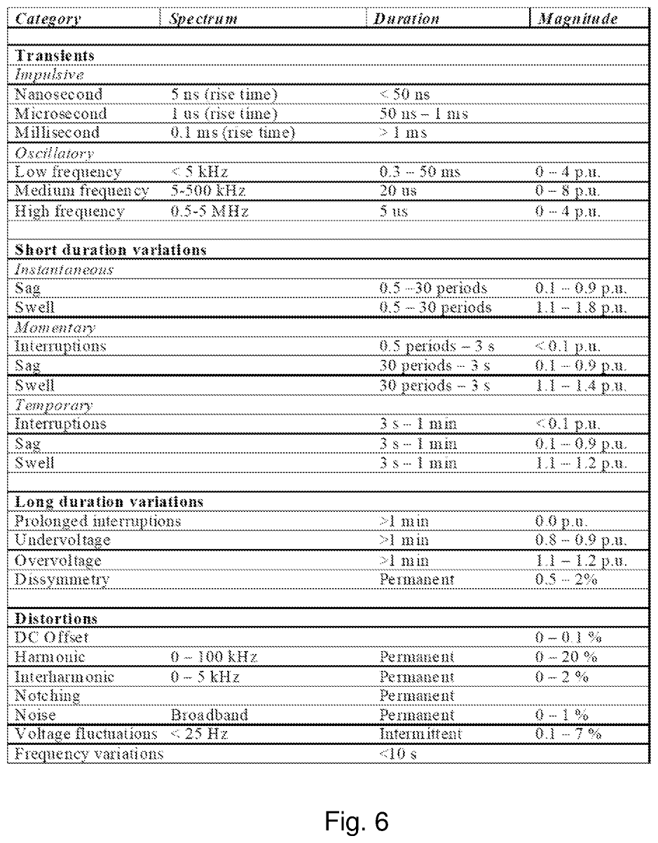

FIG. 6 reports a table with the Power Quality magnitudes, which can be measured with the system according to the invention.

### DETAILED DESCRIPTION OF THE INVENTION

With reference to the block diagram in FIG. 1, in one embodiment of the invention, the smart socket 1 comprises the following modules: a control unit 101, a communication module 201, a supply module 301, a current sensor 401, a voltage recording module 501, a load on/off relay 601, a power factor correction circuit 701, a relay module for interfacing towards the load 801 and possibly pins 901 for the direct connection between the load and the control unit.

The single components of the system will now be described.

### 1) Control Unit

The unit is based, for example, on the Arduino Due board with the following specifications:

| Processor | Atmel SAM3X8E Arm Cortex-M3 MCU | |
|---|---|---|
| Operating Voltage | 3.3 | V |
| Input Voltage | 7-12 | V |
| (recommended) | | |
| Input Voltage | 6-16 | V |
| (limits) | | |
| Digital | 54 (of which 12 | |
| I/O Pins | provide PWM output) | |
| Analog Input Pins | 12 | |
| Analog Output Pins | 2 (DAC) | |
| Flash Memory | 512 KB all available | |
| | for the user applications | |
| SRAM | 96 KB (two banks: | |
| | 64 KB and 32 KB) | |
| Clock Speed | 84 | MHz |

### 2) Communication Module

Depending on the needs, different communication modules can be used for interfacing with the supervision unit including, for example, XBEE, Ethernet SHIELD, Bluetooth, WIFI Shield and the like.

### 3) Supply Module

In an advantageous configuration, the supply module is produced by means of three supply sub-modules, each of which being composed of an isolation transformer, a diode bridge, capacitors and a voltage regulator, used for supplying respectively:
the control unit;
the load interface relay module;
the power factor correction circuit;
the load on/off relay.

In particular, the main components of the supply modules are:
Isolation transformer: it allows the grid voltage to be transformed into a lower voltage. When choosing the transformer, it is necessary to consider that the tolerable input voltage (primary side voltage) must be higher than 230 VAC (standard grid voltage), this is because the device is conceived and developed with the aim of being able to record voltages higher than 230 V working (overvoltage and swell) by means of the voltage recording module, consequently the choice of classical transformers at 230 VAC would prevent such aim from being reached, resulting in the destruction of the transformer, and consequently the interruption of the supply. Similarly, the device is also conceived and developed to record voltages lower than 230 VAC (sag and undervoltage), consequently the secondary side voltage must lie within the range of admissible voltages going into the voltage regulator in these particular cases, too. Consequently, possible isolation transformer choices are:

| | PRIMARY | SECONDARY |
|---|---|---|
| | ADMISSIBLE | ADMISSIBLE |
| | VOLTAGE | VOLTAGE |
| ISOLATION TRANSFORMER | 0/400 VAC | 0/24 VAC |
| ISOLATION TRANSFORMER | 0/500 VAC | 0/36 VAC |

Also note that, as the isolation transformer is “only” used for transforming the grid voltage into a lower voltage and not as a measurement transformer, it can be replaced with a simple voltage divider, opportunely dimensioned, so as to generate an output voltage, which lies within the input range of the voltage regulator. Clearly, the resistances chosen must be able to withstand the voltage to which they are subjected without burning.
Rectifier bridge: allows the voltage from the transformer and from the voltage divider to be rectified.
Voltage regulator: allows the stabilization of the supply voltage going into the various modules. As the voltage coming out of the rectifier bridge will have an extremely wide range, it is necessary to use a voltage regulator with an equally wide interval of admissible input voltage values. For this reason, one possible choice of regulator is given by the step-down voltage regulator d24v3f5, which presents a wide range of admissible input voltage ranging from 7 to 42V.
Capacitors: these are used to reduce the ripple and avoid possible spikes in voltage, which are potentially damaging to the regulator itself.

### 4) Current Sensor

The board shown in FIG. 2 comprises the sensor ACS714 developed by Allegro Microsystems. It is a linear current sensor based on the Hall effect, which has a low resistance (˜1.2 m) of the electric circuit and galvanic isolation higher than 2.1 kV RMS. This version accepts a module bidirectional input current higher than 30 A and an output proportionate to the recorded current value, centered on 2.5 V if supplied at 5 V, centered at 1.65 V if supplied at 3.3 V, with a typical error of ±1.5%. The sensor works at 5V and has a sensitivity of 66 mV/A.

Such sensor was only used for financial reasons and, as can be seen from the brief description, besides not offering elevated precision, presents no internal circuit, which can compensate the offset. Also note how the sensor is conceived to work with input voltage equal to 5 VDC, however, the board used allows a maximum voltage on the analog pins equal to 3.3 V, therefore, the sensor ACS714 is supplied with such voltage. Such choice causes no significant increase in the measurement error.

In fact, an integrated LM4132 3.3V, shown in FIG. 3, was used to increase the precision of the measurement, so as to reduce possible fluctuations on the VCC pin of the sensor.

The optimal solution, for control units at tolerant 3.3V, is represented by the use of Hall effect current sensors, with supply voltage equal to 3.3v or, if sensors with a higher supply voltage are desired, it is advantageous to use either bidirectional logical level transducers 3.3V-5V (in this case for VCC=5 VDC), or adapt the output voltage, so that it is between 0 and 3.3 V, generally more refined, so as to provide more precise measurements, which can compensate any offset.

### 5) Voltage Recording Module

The module is used for acquiring the single samples of the instant voltage. With reference to FIG. 4, it is composed of:
Precision AC-AC transformer. The same transformers adopted for producing the supply modules cannot be used for the application since extremely elevated measurement precision is required, for this reason it is advantageous to use a voltage transformer with a precision class equal to 0.2. The same indications stated previously apply for the dimensioning of the transformer (primary side voltage).
Sampling resistors, used for adapting the secondary side voltage of the transformer to the input voltage of the analog pins. Precision resistors (tolerance≈1%) with a sufficiently small value (in the order of a few Ohms) are typically used to improve the precision of the measurement, this is because, as it is a voltage measurement, the impedance of the analog pin of the board must be much greater than the impedance of the resistance on which the measurement is taken.
   6) Load on/Off Relay

The relay is a switch with one or more electrical contacts driven by an electromagnet when the coil of the same is crossed by a current. This relay is controlled by the control unit based on the signal sent by the user via the control platform and allows the load to be activated or disabled from the mains. Naturally, electronic switches, such as SCR and the like can also be used.

### 7) Power Factor Correction Circuit

The power factor correction circuit is made up of three relays arranged parallel connected to an equal number of correction capacitors, which are activated by the control unit. The power factor correction unit has two operating modes:
I mode: only the first two relays work, connected to an equal number of “fixed” correction capacitors (whose value cannot be modified), which are operated according to the phase recorded, so as to reduce it and lessen the reactive power and consequently increase both the efficiency and the useful life of the electric load connected to the socket;
II mode: only the third relay works, connected to a correction capacitor chosen by the user, which is activated according to the phase recorded.
   The shift between the two operating modes is carried out by a switch.

More generally, the power factor correction circuit comprises a battery of capacitors, in parallel, which can be excluded individually by means of break devices arranged in series, such as relays, electronic switches or the like, driven by the control unit, to introduce a capacitive reactance into the supply circuit of the load, so as to compensate, at least partially, for the inductive reactance of the load, so as to take the power factor to values higher than 0.7, preferably higher than 0.8, typically higher than 0.9.

### 8) Load Interface Relay Module

The module is made up of various relays or electronic switches, which are activated by the control unit according to the signal sent from the control platform allowing the socket to be connected directly to the single commands of the electric load, for example they can be used for replacing/supporting the electromechanical buttons found in various household appliances, so as to operate a particular program depending on the needs.

Advantageously, the socket can be included as part of a system for monitoring the operating parameters of one or more loads in a power grid. Such system, whose block diagram is shown in FIG. 5, comprises one or more supervision units 3 interfaced with one or more smart sockets 1 for reading data related to the mains voltage and current drawn by the load (s) 2 when such smart socket (s) are inserted in series between the electric mains and the load. Besides reading and processing the electrical data from the socket 1, advantageously, the supervision unit 3 can remotely control both the socket 1 and the load 2 connected thereto, creating a node of a Smart Grid network.

Specifically, the control unit 901 of the socket 1 can receive command signals sent by the user through the communication module 201, so as to remotely control both the turning on/off of the socket via the load on/off relay 601 and the selection of a particular load program by means of the load interface relay module 801 and/or the digital and analog pins 901 of the control unit 101. Clearly, the latter function (remote program selection), presupposes an invasive and personalized intervention for each load, involving the need to access the printed circuit board and/or the electromechanical buttons physically, all the more so if a direct interface is made between the control unit and the load itself by means of special pins, as shown in FIG. 1.

By implementing such functionality, it is possible to achieve smart management of the electric load, so as to regulate its working, optimizing consumption or other performance indexes.

With regard to the recorded parameters, the following table summarizes the possible measurements, which can be taken with the system according to the invention.

Summary Table

| Magnitude to be | Measurement | |
|---|---|---|
| measured | Taken | Where |
| CURRENT | | |
| Working Value | Yes | Socket |
| Medium Value | Yes | Control Platform |
| Maximum Value | Yes | Control Platform |
| Minimum Value | Yes | Control Panel |
| Instantaneous Value | Yes | Saved inside the memory |
| | | of the control unit and |
| | | subsequently sent to the |
| | | control platform for |
| | | visualization and processing |
| VOLTAGE | | |
| Working Value | Yes | Socket |
| Medium Value | Yes | Control Platform |
| Maximum Value | Yes | Control Platform |
| Minimum Value | Yes | Control Platform |
| Instantaneous Value | Yes | Saved inside the memory |
| | | of the control unit and |
| | | subsequently sent to the |
| | | control platform for |
| | | visualization and processing |
| LOAD PHASE | | |
| Phase | Yes | Socket |
| Power Factor | Yes | Control Platform |
| POWER | | |
| Active Power | Yes | Control Platform |
| Reactive Power | Yes | Control Platform |
| Apparent Power | Yes | Control Platform |

As stated above, it is possible to implement the power factor correction of the load 2 connected to the socket 1 by means of the power factor correction circuit 701 in the smart socket 1, so as to obtain multiple benefits:
a reduction in dissipated energy. In fact, a corrected load allows users to pay only for the energy effectively used. For example: In a load with inductive cos φ=0.70, only 70% of the power supplied by the transformer in the cabin is used to produce useful work, while the rest serves to produce the reactive energy requested by the load and dispersed, in part, in the form of heat, by Joule effect;
an increase in the power available on the supply systems;
a reduction in voltage drops, with positive consequences on the working of users' equipment;
a reduction in energy loss in the conductors caused by the reduced intensity of current in circulation at the same power.

Advantageously, the system is able to perform Power Quality analyses. This term refers to a wide range of electromagnetic phenomena, which characterize the voltage and/or current in a given point of the electric system. By issuing the recommendations Std. 1159-1995, the IEEE proposed a subdivision of the phenomena, the root of disturbances caused in the electrical systems as shown in the table in FIG. 6.

1-12. (canceled)

13. A smart socket for monitoring electric operating parameters of a load in an electric power network, which socket comprises at least one voltage sensor and a current sensor interfaced with a control unit configured to read the electric mains voltage and drawn current values when the socket is inserted between the load and the electric power network, a communication module interfaced with the control unit to send data and receive controls from a remote supervision unit, the socket further comprising load operation control devices which operate according to the controls received from the communication module and/or to the controls preset in the control unit characterized in that the socket is further adapted to read the working electrical parameters of said load and provide an output Power Quality analysis of the mains.

14. The socket according to claim 1, wherein said working electrical parameters are chosen in the group comprising: rms voltage value, mean voltage value, maximum voltage value, minimum voltage value, rms current value, mean current value, maximum current value, minimum current value, power factor, active power, reactive power, apparent power.

15. The socket according to claim 2, wherein the load control devices comprise modules which act on the supply circuit of the load.

16. The socket according to claim 3, wherein the modules which act on the supply of the load comprise a break device of the current circulation on the load, such as a relay, an electronic switch or the like, driven by the control unit to turn the load on/off.

17. The socket according to claim 1, wherein the load control devices comprise a power factor correction circuit which reduces the reactive power on the load.

18. The socket according to claim 5, wherein the power factor correction circuit comprises a battery of capacitors in parallel which can be excluded individually by means of break devices arranged in series, such as relays, electronic switches or the like, driven by the control unit to introduce a capacitive reactance into the supply circuit of the load so as to at least partially compensate for the inductive reactance of the load so as to take the power factor to values higher than 0.7, preferably higher than 0.8, typically higher than 0.9.

19. The socket according to claim 1, wherein the load control devices comprise elements for interfacing the control unit with the load so as to allow the control unit to set at least part of the respective operating parameters directly on the load.

20. The socket according to claim 1, wherein the control unit is configured to receive control signals from the supervision unit for remotely turning on/off, and more in general controlling the operation of the load, thus optimizing consumption or other performance indexes according to the monitored operating parameters.

21. A system for monitoring operating parameters of one or more loads present in an electric power network, which system comprises one or more supervision units interfaced with one or more smart sockets according to claim 1 in order to read data related to the electric mains voltage and current drawn by the load(s) when such smart socket(s) are inserted in series between the electric mains and the load.

22. The system according to claim 9, wherein the supervision unit interfaces with the smart socket(s) by means of a wired or wireless network, particularly by means of Bluetooth, Wifi, Zigbee networks or the like.

23. The system according to claim 9, wherein the supervision unit is configured to read electric parameters by means of one or more smart sockets and to process such parameters to output a Power Quality analysis of the electric power network.

24. The system according to claim 11, wherein the Power Quality analysis comprises processing one or more parameters selected from the list consisting of: effective voltage value, mean voltage value, maximum voltage value, minimum voltage value, effective current value, mean current value, maximum current value, minimum current value, power factor, active power, reactive power, apparent power.

25. The system according to claim 11, wherein the Power Quality analysis comprises extrapolating one or more categories of electrical disturbances of the electric mains voltage chosen in the group comprising: impulsive transients, oscillatory transients, instantaneous short duration variations, momentary short duration variations, temporary short duration variations, long duration variations, prolonged interruptions, undervoltages, overvoltages, dissimmetries, distortions due to DC offset, harmonic distortions, interharmonic distortions, notching distortions, broadband noise distortions, voltage fluctuations distortions, frequency variation distortions.
